(19) United States
(12) Patent Application Publication
(10) Pub. No.: US 2010/0130117 A1
(43) Pub. Date: May 27, 2010

(54) METHOD AND APPARATUS FOR DATA CENTER AIR CONDITIONING

(76) Inventor: Arthur E. Larsen, Lincoln, RI (US)

Correspondence Address: SALTER & MICHAELSON;THE HERITAGE BUILDING, 321 SOUTH MAIN STREET, PROVIDENCE, RI, 029037128, US

(21) Appl. No.: 12/690,454

(22) Filed: Jan. 20, 2010

(51) Int. Cl. H05K 5/02; F24F 7/007

(52) U.S. Cl. 454/184; 454/230

(57) ABSTRACT

Modular data center containers with modular components suitable for use with rack or shelf mount computing systems currently use cooling methods that do not include economizers due to size constraints of structural steel support infrastructure associated with modular data centers and removable economizers to facilitate portability of modular data centers. The modules allows introduction of outside air to the cooling cycle with the unique elements embodied within airside economizer components. The modules in conjunction with the data center represents a new and useful process to allow the economizer elements to bring outside air into the modular data center cooling cycle.

### FIELD OF THE INVENTION

The present invention relates in general to a method and apparatus for data center cooling. More particularly, the present invention relates to an improved method and apparatus that allows outside air to enter the cooling cycle of the data center to thus reduce mechanical cooling requirements.

### BACKGROUND OF THE INVENTION

Modular data centers are typically an intermodal shipping container that is delivered to a particular site with all computer components and cooling systems installed and ready for hook up at the site to cooling fluids and electrical power. Delivery and removal of containers as well as structural elements of storage on site make the use of currently used economizers impossible. The currently used cooling systems for modular data centers have no airside economizer element. In this regard reference is made to an example found in U.S. Pat. No. 7,278,273 which describes a data center that uses an internal vent system that only teaches the use of inlet and outlet vents that provide only convection flow through the data center shelves.

A problem associated with existing economizer structures is the fact that they use opposed blade dampers. These cannot be used with data center structures for the following reasons
1) free area (the space that air flows through) would require larger openings in the return and outside air openings of the data center structure. There is no way to increase the size of the openings due to the limited space inside for the return damper and for the outside air damper to introduce air to the cooling air flow cycle. The cfm of air required for an economizer cannot be introduced into the cooling air flow cycle using current economizer designs.
2) Weight requires additional support to carry which would also interfere with the interior air cooling spaces in the container.
3) Depth of economizer does not allow arrangement of containers in side by side storage.
4) Depth and weight does not allow for easy installation and removal of economizers on site to meet the needs of portability.

Accordingly, it is an object of the present invention to provide an improved cooling technique that is in particular for use in association with an existing data center.

Another object of the present invention is to provide a data center cooling apparatus as expressed above and in which an economizer apparatus can be readily attached with an existing data center structure and without requiring any substantial modification to the data center structure.

Still another object of the present invention is to provide an airside economizer useable with a data center to allow outside air to enter the existing cooling cycle of the data center to thus reduce internal mechanical cooling requirements.

A further object of the present invention is to provide an airside economizer useable with a data center and in which airside economizer modules can be readily installed on site and also readily removed on site to allow intended portability of data center containers.

Still a further object of the present invention is to provide an airside economizer useable with a data center and in which the airside economizer modules are of a size (minimum width in particular) that enable them to be readily attached to the data center, and yet are effective in providing the economizer characteristics to the data center structure.

### SUMMARY OF THE INVENTION

To accomplish the foregoing and other objects, features and advantages of the present invention there is provided a data center apparatus for controlling in an efficient manner the cooling cycle of the data center. The apparatus comprises a data center having at least one stack of computer equipment stored therein, and including an enclosing housing. The data center also includes a re-circulation system therein that includes internal means for re-circulating air in a cooling cycle about the computer equipment. In accordance with the invention there is provided one or more economizer structures each attached to at least one side of the data center housing. The economizer structure comprises at least one module that includes means for introducing an auxiliary air flow to supplement the re-circulation of air in the data center.

In accordance with other aspects of the present invention the economizer modules enable outside air to be introduced to the modular data center cooling cycle; the economizer modules are provided segmented in length and installed along the exterior of the modular data center housing; the modules are removably attached to the data center housing; including an exhaust channel located within the modular data center for conveying hot air to be exhausted; preferably the economizer module is at the bottom of the data center housing and the exhaust channel extends therefrom to a top of the data center housing where a vent is provided through which exhaust occurs; including a sash damper and a sash damper housing enclosing the sash damper and a spring return sash damper roller; including a filter in the module; including a first damper in the module and a second damper in the return air damper constructed of a material capable of being formed into and unwound from a roll; including a sash damper motor for modulating the damper position between open and closed positions, and the damper is a sash damper; including a sash damper, a guide wire for controlling the sash damper and a connector for connecting the sash damper and guide wire; including damper wheels and a damper wheel track, said connector constructed of metal or plastic and capable of supporting the sash dampers, sash damper wheels and guide wire; wherein there are preferably two guide wires for connecting the sash damper connector and the damper motor; including an exhaust fan for conveying hot air from the exhaust channel to the exterior of the modular data center, and wherein the fan exhaust is to substantially match the amount of outside air introduced via the economizer module; including one or more sash damper rollers having a spring return and rotatable to allow the sash damper to roll out or retract inward; including one or more sash damper wheels attached to the sash damper connector to allow the damper to travel in the sash damper wheel track; wherein the sash damper wheel tracks allow the sash damper wheels to move freely in both directions between open and closed positions; including one or more sash damper stabilizer rods mounted on the top and bottom of the sash damper wheel track for stabilizing the sash damper from movement of air through the sash damper opening; including sash damper seals connected to the wheel tracks to provide a seal on both sides of the sash damper and to prevent moisture migration; and including a digital control system capable of controlling the economizer module in cooperation with a data center environmental control system.

### DESCRIPTION OF THE DRAWINGS

The present invention will now be readily understood and enabled by a consideration of the following detailed description taken in conjunction with the accompanying drawings, in which:

FIG. 1 is a schematic representation of a typical cooling air cycle in a modular data center;

FIG. 2 illustrates the cooling air cycle of an airside economizer introducing outside air into a modular data center, as in accordance with the present invention;

FIG. 3 schematically shows a side view of the economizer module and components;

FIG. 4 shows an airflow schematic with economizer components as in accordance with the present invention;

FIG. 5 shows a plan view of a modular data center with exhaust channel and hot air exhaust fans;

FIG. 6 shows the sash damper component detail side view;

FIG. 7 shows a plan view of the sash damper;

FIG. 8 shows the sash damper wheel guide track and sash damper stabilizer rods;

FIG. 9 shows the sash damper seals connected to the wheel track on both sides of the sash damper;

FIG. 10 shows a front view of the damper connector with wheels; and

FIG. 11 shows a modular data center with the economizer modules of the present invention attached thereto.

### DETAILED DESCRIPTION

The present invention is now described in further detail herein by reference to the accompanying drawings. The method and apparatus of the present invention allows the introduction of outside air to the cooling cycle of modular data centers. The apparatus may be in the form of a series of modules that can be readily attached to an existing data center module. These modules preferably are provided in segments to serve preferably the full length of the modular data center. These segments are of a weight that allows easy installation and removal on site. The modules of the present invention preferably have a depth that allows installation with steel structural elements of the modular data center infrastructure. Sash dampers are used to reduce the depth and weight of the economizer module.

Typical modular data centers are 40 feet long, and the modules of the present invention can be constructed in five foot segments. This would thus require eight economizer modules for each side of the data center to cover the entire length of the data center. Total economizer module quantity would thus be sixteen total economizer module lengths and quantities will also be based on the modular data center cooling system manufacturer requirements. The use of one or more airside economizer modules enables outside air to be introduced to the modular data center cooling cycle. Airside economizer modules that are segmented in length can be installed along the exterior of the modular data center. The segments are of a sufficient length and quantity to serve the intended purpose of introducing outside air to the modular data center. The economizer modules are intended to be removable and lightweight.

Modular data center containers with modular components suitable for use with rack or shelf mount computing systems currently use cooling methods that do not include economizers due to size constraints of structural steel support infrastructure associated with modular data centers. The structure of the present invention allows introduction of outside air to the cooling cycle of the data center with the unique elements thereof embodied within airside economizer components that are described in further detail hereinafter. The present invention represents a new and useful process to allow the economizer elements to bring outside air into the modular data center cooling cycle, and under a controlled manner with the particular use of damper controls.

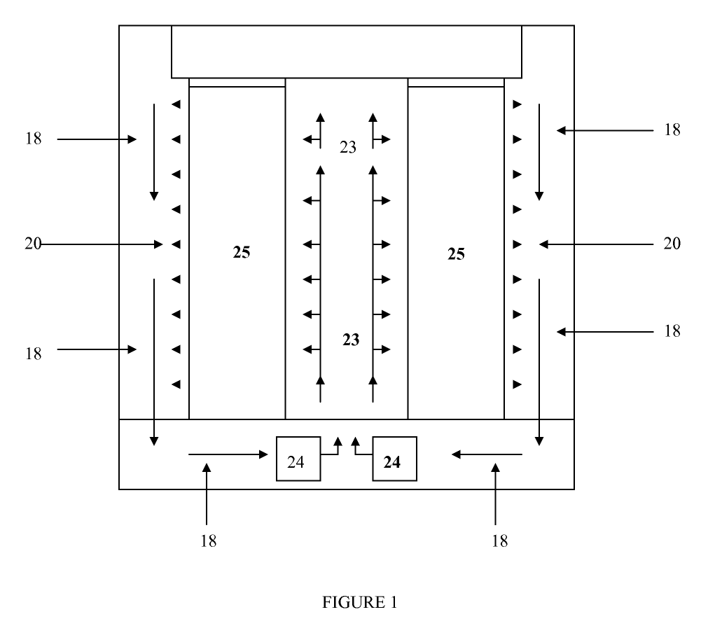

FIG. 1 shows a typical data center that may employ modular components suitable for use with rack or shelf mount computing systems, and including specifically an internal cooling system contained within the modular data center. In FIG. 1 the computer equipment is indicated at 25. This may include shelves that house several computers stacked in a column as represented at 25 in FIG. 1. FIG. 1 shows the modular data center cooling airflow with several arrows shown to indicate the air flow through the data center. The air flow is controlled by fans 24 that provide a re-circulation of air as illustrated by the series of arrows shown. Hot air from the equipment 25 is show at 20. The return hot air is represented by arrows at 18. The cooled air is indicated at 23.

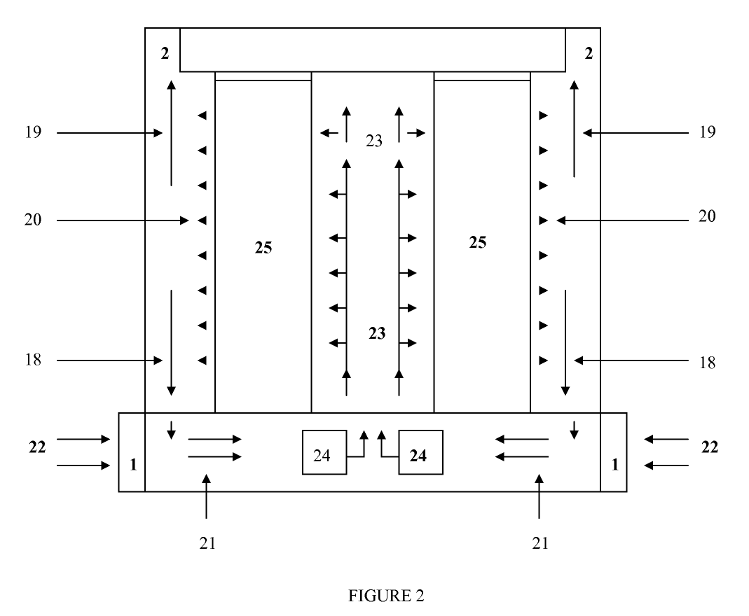

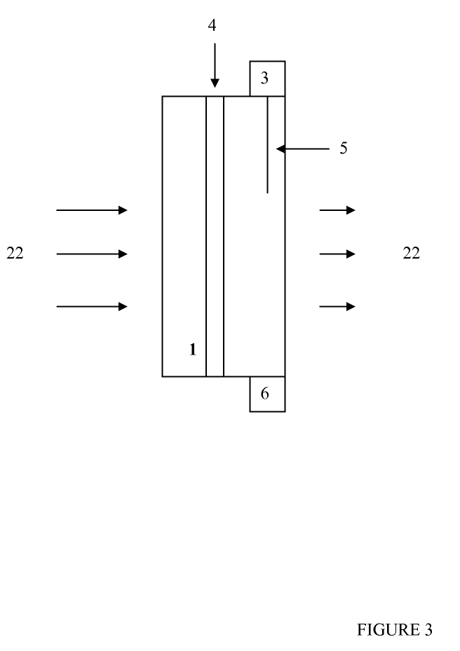

FIG. 2 shows the cooling airflow through the data center with the addition of the economizer module 1 of the present invention. The economizer also includes the exhaust channels 2 depicted in FIG. 2. Some of the same reference characters are used in FIG. 2 as illustrated previously in FIG. 1. Thus arrows 18 indicate hot air return and arrows 23 indicate the cooling air flow. Superimposed in FIG. 2 are other arrows indicating air flow as represented by the addition of the economizer module 1 of the present invention. The outside air is shown at 22 entering each of the opposite side modules 1. Further details of the modules 1 are set forth in FIGS. 3-11. The computer equipment 25 is shown with the cooling air 23 and the expelled hot air 20. The input air 22 from the outside is mixed with the hot air return as illustrated at 21, and drawn by the cooling fans 24. At the same time FIG. 2 illustrates the how air to an exhaust at 19. Thus, there could be considered a dual flow between module 1 and the exhaust at 2 through the channel that intercouples them.

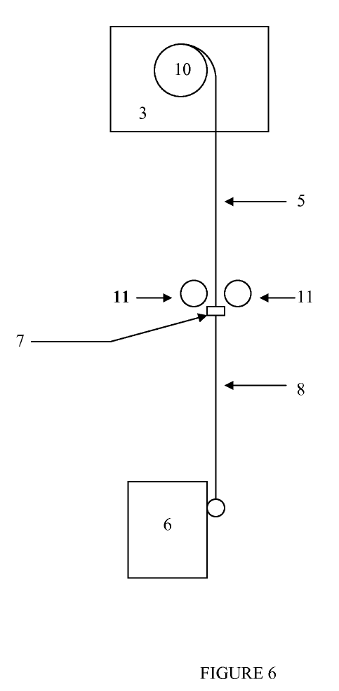

FIG. 3 shows a schematic side elevation view of the airside economizer module 1, air filter 4, sash damper 5, sash damper motor 6 and sash damper roller housing 3, and the outside air at 22. The air filter 4 may be of conventional type, and the damper motor 6 may also be conventional in design. Further details of the damper arrangement are disclosed in, for example, in FIGS. 6-10 that are described later.

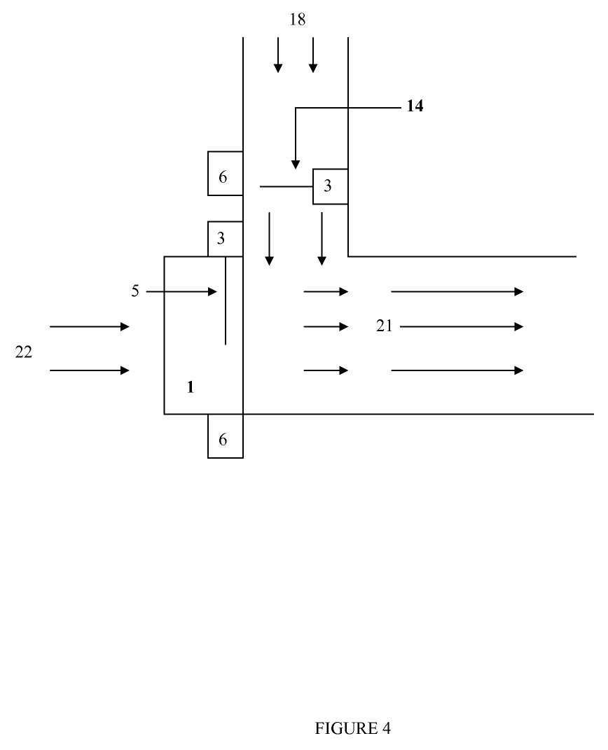

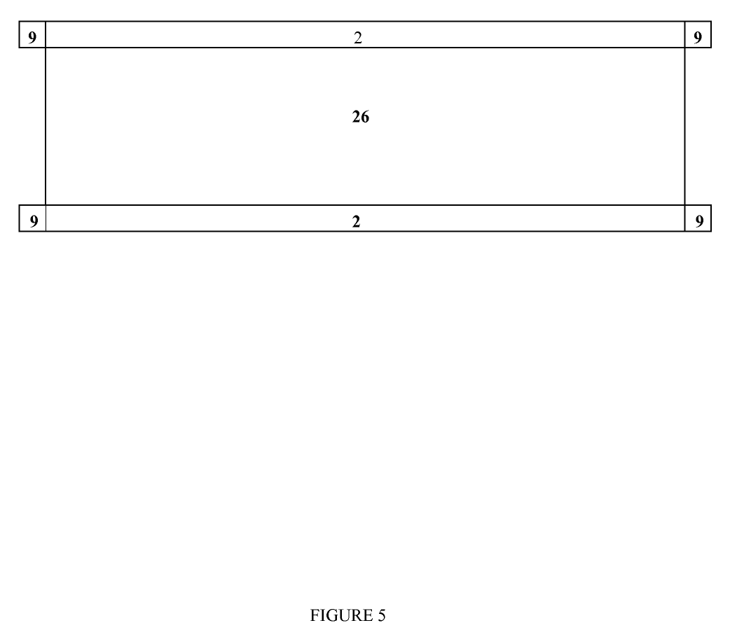

FIG. 4 shows return air sash damper 14, outside air sash damper 5, sash damper roller housing 3, sash damper motor 6, air filter 4 and economizer module 1 hot air to return 18, outside air 22, mixed hot air return and outside air 21. Thus, in FIG. 4 there is, in addition to the damper 5 at the module 1, a channel damper 14 that controls air flow in the data center. Both of these are respectively controlled from corresponding drive motors 6. FIG. 5 schematically shows exhaust channels 2, hot air exhaust fans 9 and modular data center 26. The channel 2 in FIG. 5 is essentially depicting the air flow way between the module 1 and the top output port at 2 in FIG. 2. In FIG. 5 the left hand fans 9 may be considered at forcing air into the channel 2, while the right hand fans 9 may be considered as withdrawing air from the channel 2.

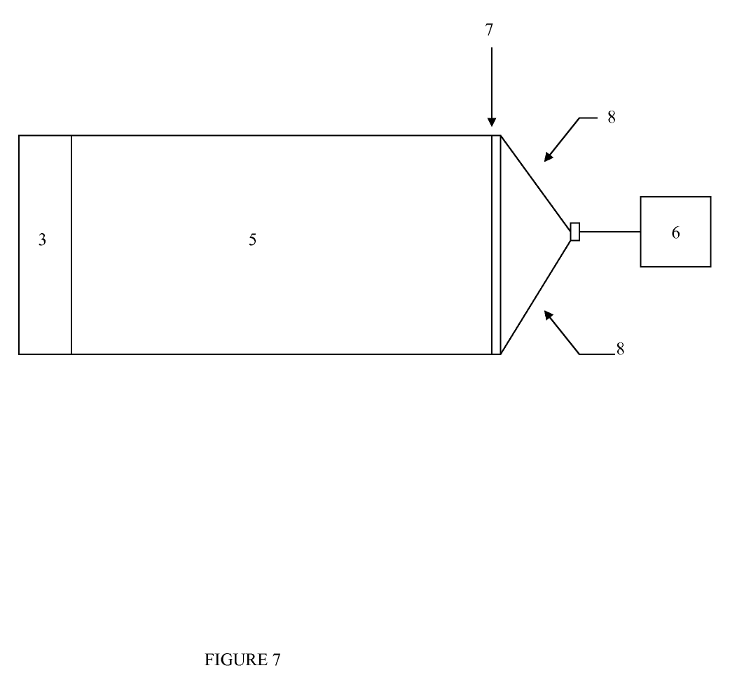

FIG. 6 schematically illustrates the sash damper components. This includes a sash damper roller 10, sash damper housing 3, sash damper 5, sash damper wheels 11, sash damper connector 7, motor guide wire 8 and damper motor 6. The sash damper roller is depicted as positioned in the housing 3. The damper connector simply couples together the sash damper 5 with the motor guide wire 8. In that way the motor 6 can control the position of the damper 5 so as to determine how much the damper closes off or opens either the channel 2 or the inlet of air at the module 1. The sash damper wheels are for positionally guiding the control wire 8 and damper 6. FIG. 7 also shows the same sash damper components as disclosed in FIG. 6. This includes the roller housing 3, sash damper 5, sash damper connector 7 motor guide wire 8 and damper motor 6. It is noted from FIG. 7 that the wire 8 is actually separated into two wires connected, through the connector 7, to opposite ends of the sash damper 5.

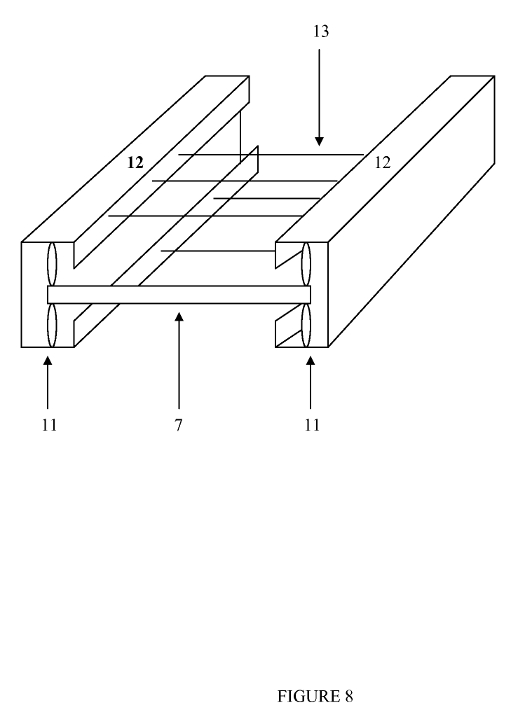

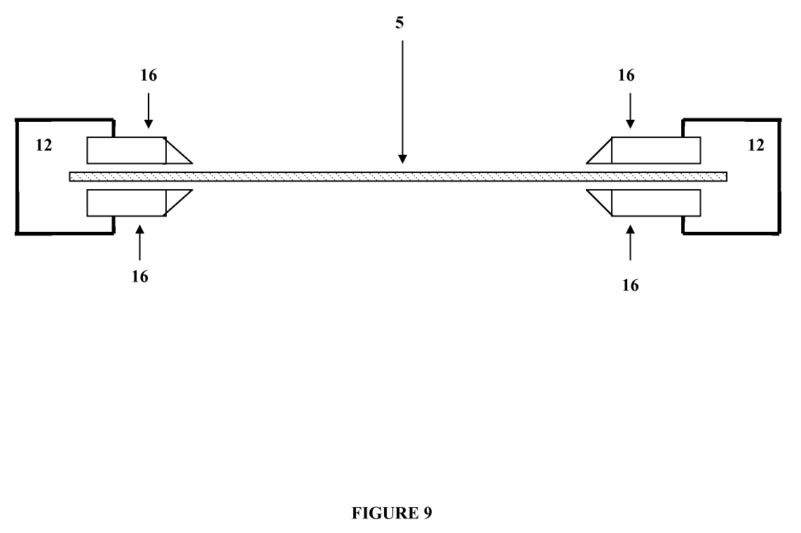

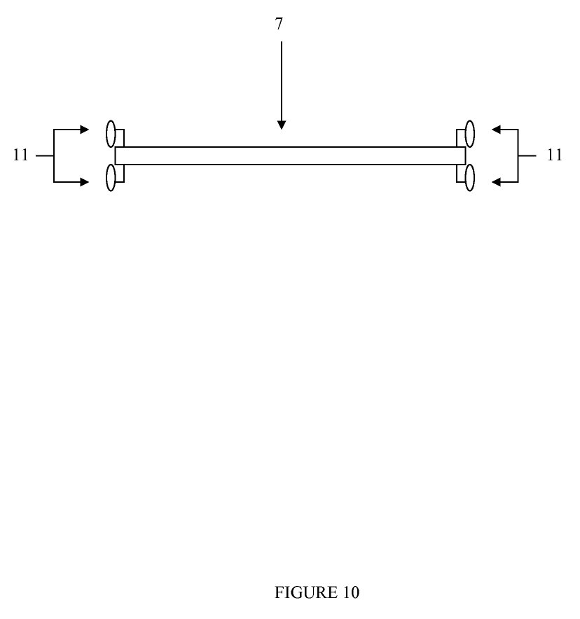

FIG. 8 is a further schematic illustration of certain components of the system. This includes sash damper connector 7, sash damper wheels 11, sash damper wheel track 12 and sash damper stabilizer rods 13. The stabilizer rods 13 maintain the tracks 12 in a proper position relative to each other. This arrangement allows the damper to properly slide between open and closed positions thereof. The arrangement shown in FIG. 8 can be used for both the damper 5, as well as the damper 14 depicted in FIG. 4. FIG. 9 is still a further schematic view of the damper components taken from an orthogonal view to that shown in FIG. 7. This includes sash damper seals 16 attached to the wheel guide track 12 on both sides of the sash damper 5. The damper seals also form additional guides for the damper, and apply to either damper 5 or damper 14. FIG. 10 schematically shows sash damper connector 7 and sash damper wheels 11.

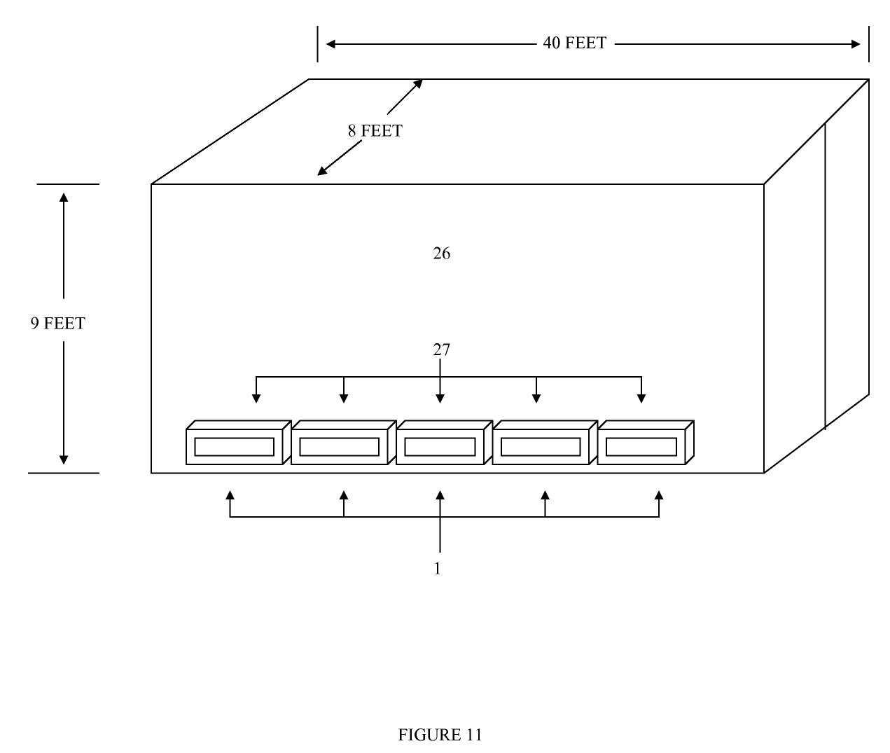

FIG. 11 schematically illustrates a modular data center perspective side view with the economizer modules attached. Economizer modules 1 preferably have a module depth on the order of 6 inches as at 27 in FIG. 11. The series of modules are attached to the side of the modular data center 26. Each of the modules may be of the type previously detailed in the earlier FIGURES. The modules 1 preferably extend at least along a major length of the side of the data center 26. For a 40 foot length five modules are depicted in FIG. 11. In that case each module may be eight feet long. The modules 1 have a length preferably in a range of 4-12 feet depending upon the size of the particular data center. The data center 26 may be considered as comprising an outer housing of metal to which the individual modules 1 are attached in a relatively simple manner. Also they are attached so that they can also be readily removed. In addition to the modules 1, but not shown in FIG. 11, is a top vent structure incorporated into the data center, as depicted in FIG. 2 at the area above 2. See also the vent arrangement of FIG. 5. In FIG. 11 the data center 26 is represented by way of example as having dimensions of 40 feet long, 9 feet high and 8 feet wide. Of course, other dimensions may also apply to the data center 26.

The following are some of the features of the present invention. In the invention one or more airside economizer modules are used and enable outside air to be introduced to the modular data center cooling cycle. Airside economizer modules are preferably provided segmented in length and installed along the exterior of the modular data center, particularly a sidewall of the data center, and more particularly along opposed sidewalls The segments are of a sufficient length and quantity to serve the intended purpose of introducing outside air to the modular data center. The modules are intended to be removable and lightweight. Due to space constraints in a typical data center the modules of the present invention are provided with a restricted width, preferably on the order of six inches. This is not possible with existing economizer structures such as an opposed blade damper. However, the sash damper structure of the present invention in particular has been found as effective in providing the economizer characteristics, but with a size and width that enable the economizer structure to be readily attached to sides of the data center housing. The attachment itself can be by conventional means such as well known fasteners. The sash damper arrangement enables the proper re-circulation control yet with a minimum of width between data center housings.

In accordance with further features of the present invention one or more exhaust channels located within the modular data center are used convey hot air that is to be exhausted. One or more sash damper roller housings are provided to enclose the sash damper and a spring return sash damper roller. Filters are used to remove pollutants. The sash dampers are provided to control the amount of air allowed through sash damper openings and into the cooling cycle. The sash damper is preferably made of rubber or any material that has the ability to be rolled and unrolled and has sufficient thickness and strength to operate properly. The sash damper motors modulate the sash damper position between open and closed. The sash damper connectors attach to the sash dampers, the sash damper guide wires and the damper wheels. The sash damper connector is preferably made of metal or plastic and capable of supporting the sash dampers, sash damper wheels and guide wire.

In accordance with still other features of the present invention the module is provided with exhaust fans that convey hot air from exhaust channels to the exterior of the modular data center. The fan exhaust is meant to match the amount of outside air introduced via the economizer module. A fan can be provided at both ends of the channel or only at the outlet end (top in FIG. 2).

The sash damper roller has a spring return and rotates to allow the sash damper to roll out or retract inward. The sash damper wheels are preferably attached to the sash damper connector to allow the damper to travel in the sash damper wheel track. The sash damper wheel tracks allow the sash damper wheels to move freely in both directions between open and closed positions. The sash damper stabilizer rod are preferably mounted on the top and bottom of the sash damper wheel track and stabilize the sash damper from movement of air through the sash damper opening. The air sash dampers (5 and 14) control the amount of air returned to the cooling cycle. There is also preferably provided digital control systems capable of controlling all elements of the present invention and communicating with modular data center environmental control systems. The sash damper seals connect to the sash damper wheel tracks and provide an air seal on both sides of the sash damper and prevent moisture migration.

The following description is presented to enable any person skilled in the art to make and use the invention. Descriptions of specific embodiments and applications are provided only as examples and various modifications will be readily apparent to those skilled in the art. The general principles defined herein may be applied to other embodiments and applications without departing from the spirit and scope of the invention. Thus the present invention is to be accorded the widest scope encompassing numerous alternatives, modifications and equivalents consistent with the principles and features disclosed herein. For purpose of clarity, details relating to technical material that is known in the technical fields related to the invention have not been described in detail so as not to unnecessarily obscure the present invention. One example of a variation is that the modules 1 could be attached at the top of the data center housing rather than at the bottom as depicted in the drawings herein. In that case the venting is from the top of the data center housing.

### List of Components

1. Economizer module

2. Exhaust channel

3. Sash damper roller housing

4. Air filter

5. Sash damper

6. Sash damper motor

7. Sash damper connector

8. Sash motor guide wire

9. Exhaust fans

10. Sash damper roller

11. Sash damper wheels

12. Sash damper wheel track

13. Sash damper stabilizer rods

14. Return air sash damper

15. Economizer digital control element

16. Sash damper seals

17. not used

18. Hot air to return

19. Hot air to exhaust

20. Hot air

21. Mixed hot air return and outside air

22. Outside air

23. Cooling air

24. Cooling fans

25. Computer equipment

26. Modular data center

27. Module depth which may be 6 inches

What is claimed is:

1. A data center apparatus comprising:
a data center having at least one stack of computer equipment stored therein, and including an enclosing housing;
the data center also including a re-circulation system therein that includes internal means for re-circulating air in a cooling cycle about the computer equipment;
an economizer structure attached to at least one side of the data center housing;
the economizer structure comprising at least one module that includes means for introducing an auxiliary air flow to supplement the re-circulation of air in the data center.

2. The apparatus of claim 1 including one or more economizer modules that enable outside air to be introduced to the modular data center cooling cycle.

3. The apparatus of claim 2 wherein the economizer modules are provided segmented in length and installed along the exterior of the modular data center housing.

4. The apparatus of claim 3 wherein the modules are removably attached to the data center housing.

5. The apparatus of claim 1 including an exhaust channel located within the modular data center for conveying hot air to be exhausted.

6. The apparatus of claim 5 wherein the economizer module is at the bottom of the data center housing and the exhaust channel extends therefrom to a top of the data center housing where a vent is provided through which exhaust occurs.

7. The apparatus of claim 1 including a sash damper and a sash damper housing enclosing the sash damper and the spring return sash damper roller.

8. The apparatus of claim 1 including a filter in the module.

9. The apparatus of claim 5 including a first damper in the module and a second damper in the channel with the damper constructed of a material capable of being formed into and unwound from a roll.

10. The apparatus of claim 1 including a sash damper motor for modulating the damper position between open and closed positions, and the damper is a sash damper.

11. The apparatus of claim 1 wherein the economizer module includes a sash damper, a guide wire for controlling the sash damper and a connector for connecting the sash damper and guide wire.

12. The apparatus of claim 11 including damper wheels and a damper wheel track, said connector constructed of metal or plastic and capable of supporting the sash dampers, sash damper wheels and guide wire.

13. The apparatus of claim 12 wherein there are two guide wires for connecting the sash damper connector and the damper motor.

14. The apparatus of claim 12 including an exhaust fan for conveying hot air from the exhaust channel to the exterior of the modular data center, and wherein the fan exhaust is to substantially match the amount of outside air introduced via the economizer module.

15. The apparatus of claim 14 including one or more sash damper rollers having a spring return and rotatable to allow the sash damper to roll out or retract inward.

16. The apparatus of claim 15 including one or more sash damper wheels attached to the sash damper connector to allow the damper to travel in the sash damper wheel track.

17. The apparatus of claim 16 wherein the sash damper wheel tracks allow the sash damper wheels to move freely in both directions between open and closed positions.

18. The apparatus of claim 17 including one or more sash damper stabilizer rods mounted on the top and bottom of the sash damper wheel track for stabilizing the sash damper from movement of air through the sash damper opening.

19. The apparatus of claim 18 including sash damper seals connected to the wheel tracks to provide a seal on both sides of the sash damper and to prevent moisture migration.

20. The apparatus of claim 1 including a digital control system capable of controlling the economizer module in cooperation with a data center environmental control system.
